(19) United States
(12) Patent Application Publication
(10) Pub. No.: US 2011/0254404 A1
(43) Pub. Date: Oct. 20, 2011

(54) ELECTROSTATIC DRIVE, MICROMECHANICAL COMPONENT, AND MANUFACTURING METHOD FOR AN ELECTROSTATIC DRIVE AND A MICROMECHANICAL COMPONENT

(75) Inventors: Tjalf Pirk, Stuttgart (DE); Stefan Pinter, Reutlingen (DE); Michael Krueger, Reutlingen (DE); Joerg Muchow, Reutlingen (DE); Joachim Fritz, Tuebingen (DE); Christoph Friese, Reutlingen (DE)

(73) Assignee: Robert Bosch GMBH, Stuttgart (DE)

(21) Appl. No.: 13/124,625

(22) PCT Filed: Aug. 24, 2009
(86) PCT No.: PCT/EP09/60881

§ 371 Date: Jun. 28, 2011

(30) Foreign Application Priority Data
Oct. 20, 2008 (DE) 10 2008 042 964.3

(51) Int. Cl. H02N 1/00; H05K 13/04

(52) U.S. Cl. 310/300; 29/592.1

(57) ABSTRACT

An electrostatic drive is described having an inner frame, at least one intermediate frame, which encloses the inner frame, and an outer frame, which encloses the inner frame and the at least one intermediate frame, each two adjacent frames of the inner, intermediate, and outer frames being connected to one another via at least one spring element, the spring elements, via which each two adjacent frames of the inner, intermediate, and outer frames are connected to one another, being situated in such a way that the longitudinal directions of the spring elements lie on a common longitudinal spring axis, and electrode fingers being situated on frame bars, which are oriented parallel to the longitudinal spring axis, of the inner frame, the at least one intermediate frame, and the outer frame. A manufacturing method for an electrostatic drive, a micromechanical component, and a manufacturing method for a micromechanical component, are also described.

### FIELD OF THE INVENTION

The present invention relates to an electrostatic drive and a manufacturing method for an electrostatic drive. Furthermore, the present invention relates to a micromechanical component and a manufacturing method for a micromechanical component.

### BACKGROUND INFORMATION

Micromechanical components having a displaceable actuator frequently have an electrostatic drive and/or a magnetic drive. The forces implementable by the electrostatic drive to displace the actuator are typically less than the implementable forces of a magnetic drive, however.

In order to increase the implementable force for rotating the actuator around a rotational axis, some electrostatic drives have electrode fingers which are situated at a comparatively large distance from the rotational axis. Such an example is described, for example, in U.S. Published Patent Appl. No. 2005/0035682 A1.

The micro-oscillator element described in U.S. Published Patent Appl. No. 2005/0035682 has an inner frame and an outer frame as the electrostatic drive, the inner frame being connected via two V-springs in each case to an actuator and to the outer frame. Cross struts, which run parallel to a rotational axis of the actuator, are attached to the actuator and to the frame adjacent to the V-springs. The electrode fingers situated on the cross struts run perpendicularly to the rotational axis.

The micro-oscillator element described in U.S. Published Patent Appl. No. 2005/0035682 A1 thus ensures a greater distance between the rotational axis and the electrode fingers. However, the greater distance between the electrode fingers and the rotational axis results in a relatively small maximum displacement angle of the actuator. Furthermore, the frame having the cross struts situated thereon and the electrode fingers occupy a comparatively large installation space. This may result in problems when the micro-oscillator element is mounted in a micromechanical component.

### SUMMARY

In accordance with the present invention, the operating volume which is required for an electrostatic drive made of at least three frames having associated electrode fingers is reducible by situating the electrode fingers directly on a frame bar of the frame, the frame bars of the frame running parallel to the rotational axis during operation of the electrostatic drive. The rotational axis corresponds to the common spring longitudinal axis, on which the longitudinal directions of the spring elements lie.

By directly situating the electrode fingers on the frame bars parallel to the rotational axis, which may be referred to as the spring longitudinal axis, the cross struts which are typically used for situating the electrode fingers on the frame may be dispensed with. The volume required by the cross struts, which typically extend away from the frame, is thus dispensed with. This ensures a reduction of the operating volume of the electrostatic drive according to the present invention. A micromechanical component having the electrostatic drive according to the present invention may thus be designed to be smaller in a simple way.

In accordance with an example embodiment of the present invention, the electrode fingers are not attached laterally to the frame via cross struts, but rather directly to the front sides (the frame bars) of the frame. By directly situating the electrode fingers on the frame bars of the frame running parallel to the rotational axis, a comparatively greater distance is ensured between the electrode fingers and the rotational axis. This significantly increases the maximum torque achievable (per frame). Therefore, without enlarging the area of a frame, the torque may be increased by a high factor, for example, a factor of 100.

Because of the comparatively small operating volume of an electrostatic drive made of multiple frames having electrode fingers situated directly on the frame bars, the number of the frames may be increased at the same operating volume. Therefore, multiple intermediate frames may be situated between the inner frame and the outer frame. Significantly, more than three frames are preferably interleaved in one another, each two adjacent frames being connected to one another using at least one spring element. An optimal area utilization is ensured by the direct attachment of the electrode fingers to the frame bars, which run parallel to the rotational axis, of the plurality of frames. The total displacement angle by which the inner frame is displaceable in relation to the outer frame results from the sum of the individual displacement angles of two adjacent frames. The cascade formed from the plurality of frames ensures an increased total displacement angle with unchanged individual displacement angles because of the greater number of frames.

The typical electrostatic drives having electrode fingers situated spaced apart from the rotational axis have the disadvantage that the electrode fingers already emerge from the counter-electrode fingers at a comparatively small rotational angle in relation to their height. This significantly minimizes the achievable individual displacement angles between two adjacent frames. In accordance with the present invention, the comparatively small achievable individual displacement angle may be compensated for by the greater number of frames.

The inner frame, the at least one intermediate frame, and the outer frame may be understood to be rectangular frames. Of course, the connecting bars which connect the frame bars of a frame, which run parallel to the rotational axis, to one another may also be curved. The terms inner frame, intermediate frame, or outer frame do not limit the frames used to a rectangular shape.

Since the electrode fingers are attached to a complete frame, the electrostatic drive has good stability. In addition, the oscillation modes of the electrostatic drive are rotationally symmetrical around the rotational axis.

In one advantageous specific embodiment, the inner frame, the at least one intermediate frame, and the outer frame are designed in such a way that a voltage may be applied between the electrode fingers, which are situated on the frame bars of two adjacent frames of the inner, intermediate, and outer frames, the at least one spring element between the two adjacent frames being designed in such a way that a first frame of the two adjacent frames is rotatable in relation to the second frame of the two adjacent frames around the spring longitudinal axis by applying the voltage. Preferably, each frame is rotated in relation to the outer adjacent frame by an individual displacement angle. The voltages applied to the electrode fingers are controlled in such a way that the individual displacement angles add up to form a total displacement angle, by which the inner frame is rotated in relation to the outer frame. The achievable total displacement angle may be in a range around 7° in the case of a total of 11 frames, for example. In this way, an easily executable displacement of the actuator by a large displacement angle is ensured.

In particular, the longitudinal directions of the electrode fingers, which are situated on the frame bars of the inner frame, the at least one intermediate frame, and the outer frame, are oriented perpendicularly to the spring longitudinal axis.

For example, one of the spring elements, which connects one of the intermediate frames to the outer adjacent intermediate or outer frame, has a first spring stiffness, and another of the spring elements, which connects the intermediate frame to the inner adjacent inner or intermediate frame, has a second spring stiffness unequal to the first spring stiffness. The second spring stiffness may be less than the first spring stiffness. The electrode fingers which are situated on the inner adjacent frame have a smaller distance to the rotational axis than the electrode fingers which are situated on the outer adjacent frame. Each of the frames rotates by the maximum possible displacement angle at the same applied voltage due to the second bending stiffness, which is less than the first bending stiffness.

As a supplement or as an alternative thereto, the electrode fingers which are situated on an inner or intermediate frame may have a first length and the electrode fingers which are situated on the outer adjacent intermediate or outer frame may have a second length unequal to the first length. The second length is preferably less than the first length. Because of its longer frame bar, more electrode fingers may be situated on the outer adjacent frame than on the inner or intermediate frame. The electrode fingers may thus be designed to be shorter. The operating volume required for the electrostatic drive may be additionally reduced by the reduction of the second length in relation to the first length. This simplifies the positioning of the electrostatic drive in a micromechanical component.

In one specific embodiment, each of the electrode fingers includes a lower conductive area, a middle insulating layer, and an upper conductive area. The displacement of the individual frames relative to one another may be implemented in this case via SEA wiring (switch electrode actuator). The frames, which are in one plane in the deenergized state, may be rotated resonantly out of the plane.

In one alternative specific embodiment, the electrodes are each located on the outer and inner sides of the frame bars within different planes. For example, the electrodes on the outer side are situated in an upper plane and the electrodes on the inner side are situated in a lower plane. Of course, the electrodes on the outer side may also be situated in the lower plane and the electrodes on the inner side may also be situated in the upper plane. The outer and inner areas of the bars are electrically insulated from one another. By applying a voltage to one of the two electrodes in relation to the other, the frames may be tilted in relation to one another.

The electrostatic drive described in the above paragraphs may be used in a micromechanical component, the micromechanical component having an actuator which is connected to the inner frame in such a way that the actuator is rotatable around the common spring longitudinal axis by applying a voltage between the electrode fingers, which are situated on the frame bars of two adjacent frames of the inner, intermediate, and outer frames. The actuator may thus be rotated by a comparatively large total displacement angle. Since the described electrostatic drive ensures high torques, a comparatively heavy actuator may also be displaceable in the above-described micromechanical component.

The advantages described above are also ensured in the case of a corresponding manufacturing method. In particular, a layer sequence may be formed from a lower conductive layer, a middle insulating layer, and an upper conductive layer, the inner frame, the at least one intermediate frame, and the outer frame having the associated electrode fingers being structured out of the layer sequence. This allows cost-effective manufacturing of the inner frame, the at least one intermediate frame, and the outer frame. In particular, the frames may thus be shaped to fit precisely to one another. Furthermore, the above-described method ensures that the individual frames are reliably situated relative to one another in one plane, without complex alignment steps having to be executed for this purpose.

### BRIEF DESCRIPTION OF THE DRAWINGS

Further features and advantages of the present invention are explained below on the basis of the figures.

FIG. 1 shows a top view of a micromechanical component having a first specific embodiment of the electrostatic drive.

FIG. 2 shows an enlarged detail of FIG. 1.

FIG. 3 shows a cross section through the micromechanical component of FIG. 1.

FIG. 4 shows a side view of the micromechanical component of FIG. 1.

FIGS. 5A and B each show a coordinate system to explain a second specific embodiment of the electrostatic drive.

FIG. 6 shows a coordinate system to explain a third specific embodiment of the electrostatic drive.

FIG. 7 shows a coordinate system to illustrate two examples of an achievable displacement angle.

FIG. 8 shows a flow chart to illustrate a specific embodiment of the manufacturing method for an electrostatic drive.

### DETAILED DESCRIPTION OF EXAMPLE EMBODIMENTS

FIG. 1 shows a top view of a micromechanical component having a first specific embodiment of the electrostatic drive.

Illustrated micromechanical component 10 includes an electrostatic drive having an outer frame 12, multiple intermediate frames 14, and an inner frame 16. In the illustrated example, the electrostatic drive includes a total of eleven frames 12, 14, and 16. However, it is to be noted that the present invention is not restricted to a specific number of intermediate frames 14.

Outer frame 12 encloses intermediate frames 14 and inner frame 16. Intermediate frames 14 encloses inner frame 16, the innermost of intermediate frames 14 also being enclosed by remaining intermediate frames 14. The outermost of intermediate frames 14 encloses all further intermediate frames 14 and inner frame 16.

Frame 12 and/or 14 being enclosed is not to be understood as frame 12 and/or 14 being completely enclosed in three spatial directions. Instead, frame 12 and/or 14 being enclosed is understood that at least a section of a frame 12 or 14 is encompassed and/or frame 12 and/or 14 is framed in two dimensions.

Frames 12, 14, and 16 may be designed to be rectangular. For example, frames 12, 14, and 16 are each formed from two opposing frame bars 12a, 14a, and 16a and two opposing connecting bars 12b, 14b, and 16b. In each frame 12, 14, and 16, the opposing ends of the two frame bars 12a, 14a, or 16a are each connected to one another via a connecting bar 12b, 14b, or 16b. Frame bars 12a, 14a, and 16a may be designed integrally with connecting bars 12b, 14b, and 16b.

The present invention is not restricted to rectangular frames 12, 14, and 16, however. For example, connecting bars 12b, 14b, and 16b may also be designed to be curved. Frames 12, 14, and 16 are preferably shaped in such a way that their shapes are adapted to the shape of an actuator 18 of micromechanical component 10.

In the case of micromechanical component 10, actuator 18 is a mirror plate, which is preferably at least partially covered using a reflective coating. However, micromechanical component 10 may also have a different actuator instead of actuator 18, which is designed as a mirror plate.

Actuator 18 is connected via two connecting parts 20 to inner frame 16. Each of connecting parts 20 runs from one lateral surface of actuator 18 to an inner side of a frame bar 16a of inner frame 16. In particular, the longitudinal axes of connecting parts 20 may lie on a common straight line (not shown). Connecting parts 20 are preferably designed to be stiff in such a way that the instantaneous position of actuator 18 adapts to an instantaneous position of inner frame 16.

In FIG. 1, actuator 18 is oriented parallel to outer frame 12. As explained in greater detail hereafter, this position of actuator 18 parallel to outer frame 12 may be referred to as the starting position of actuator 18. In particular, actuator 18 may be in a plane which is spanned by outer frame 12 in its starting position.

Each two adjacent frames 12, 14, and 16 of frames 12, 14, and 16 are connected to one another via two spring elements 22, 24, or 26. Outer frame 12 is connected via two spring elements 22 to outermost intermediate frame 14, spring elements 22 being formed between an inner side of a connecting bar 12b and an outer side of adjacent connecting bar 14b. Two adjacent intermediate frames 14 are also connected to one another via two spring elements 24. Furthermore, inner spring 16 is connected to innermost intermediate frame 14 via two spring elements 26.

Spring elements 22, 24, and 26 may be torsion springs and/or V-springs. Spring elements 22, 24, and 26 are situated on associated frames 12, 14, and 16 in such a way that their longitudinal directions are on a common longitudinal spring axis, which is referred to hereafter as rotational axis 28. Rotational axis 28 is oriented parallel to frame bars 12a, 14a, and 16a of frames 12, 14, and 16. Connecting bars 12b, 14b, and 16b therefore run perpendicularly to rotational axis 28.

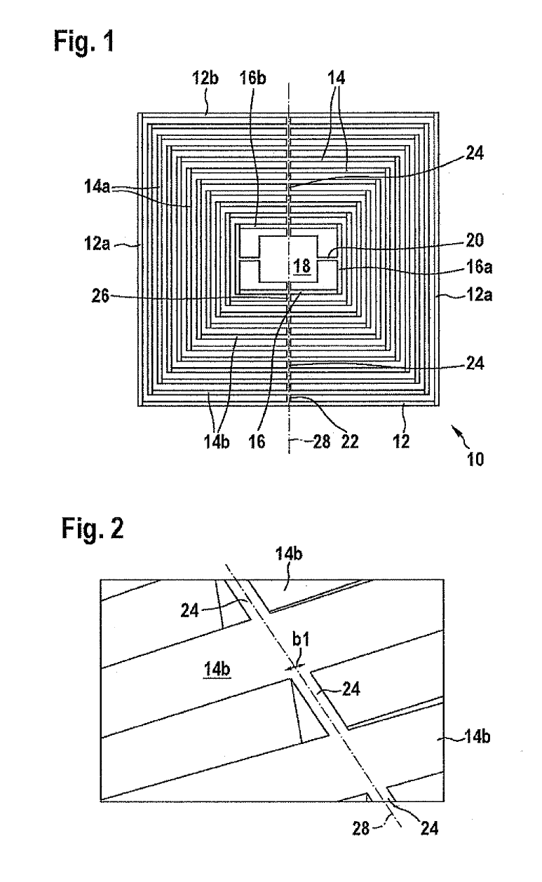

FIG. 2 shows an enlarged detail of FIG. 1.

Connecting bars 14b of several intermediate frames 14, which are shown enlarged in FIG. 2, are connected to one another via spring elements 24. One spring element 24 always runs between two adjacent connecting bars 14b. As explained in greater detail below, spring elements 22, 24, and 26 may have a comparatively large width bl. For example, width b1 of a spring element 22, 24, and/or 26 may be between 20 μm and 40 μm, in particular 30 μm.

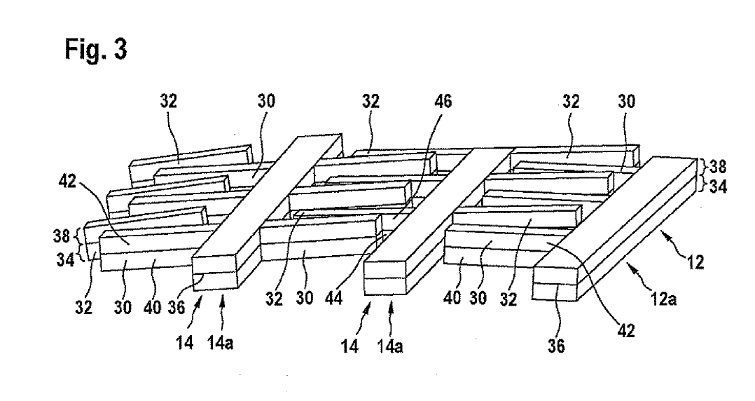

FIG. 3 shows a cross section through the micromechanical component of FIG. 1. The cross section shown runs perpendicularly through frame bars 12a and 14a of outer frame 12 and two outermost intermediate frames 14.

As shown in FIG. 3, electrode fingers 30 are situated directly on the inner side of frame part 12a of outer frame 12. Electrode fingers 30 touch the inner side of frame bar 12a. Electrode fingers 30 are oriented perpendicularly to the longitudinal direction of frame bar 12a. Therefore, they are perpendicular to rotational axis 28 (not shown).

Counter-electrode fingers 32 are situated directly on the outer side of frame bar 14a of outermost intermediate frame 14, adjacent to electrode fingers 30 of outer frame 12. Counter-electrode fingers 32, which are situated directly on the outer side of outermost intermediate frame 14, protrude into the intermediate spaces of electrode fingers 30 of outer frame 12 perpendicularly to the longitudinal direction of frame bar 14a of outermost intermediate frame 14.

Counter-electrode fingers 32 are also directly situated on the inner side of frame bar 14a of outermost intermediate frame 14. All counter-electrode fingers 32 of outermost intermediate frame 14 run parallel to electrode fingers 30 of outer frame 12. The pattern of electrode fingers 30 and counter-electrode fingers 32, which is formed between outer frame 12 and outermost intermediate frame 14, is preferably formed between all adjacent frame bars 12a, 14a, and 16a of frames 12, 14, and 16. By applying a voltage between two adjacent electrode fingers 30 and counter-electrode fingers 32, the inner one of the two associated frames 14 or 16 may be rotated around rotational axis 28 (not shown) in relation to outer adjacent frame 12 or 14.

It is to be noted here that all electrode fingers 30 and 32 are situated directly on the inner or outer sides of frame bars 12a, 14a, and 16a. Each of electrode fingers 30 and 32 has an end which is directly fastened on associated frame bars 12a, 14a, or 16a. All longitudinal areas of frame bars 12a, 14a, or 16a preferably have electrode fingers 30 and 32 on at least one side. Only the parts of frames 12, 14, and 16 which are oriented parallel to rotational axis 28 are referred to as frame bars 12a, 14a, or 16a. It is therefore possible to dispense with transverse bars, as are typically required, when positioning electrode fingers 30 and 32.

In the case of micromechanical component 10, frames 12, 14, and 16 having associated electrode fingers 30 or counter-electrode fingers 32 are constructed in multiple layers. For example, frames 12, 14, and 16 and spring elements 22, 24, and 26 are structured out of a layer sequence having a lower conductive layer 34, a middle insulating layer 36, and an upper conductive layer 38. Each of frames 12, 14, and 16, therefore includes areas of layers 34 to 38. Conductive layers 34 and 38 may include silicon and/or a metal, for example.

Each of electrode fingers 30 has a lower conductive area 40 made of the material of lower conductive layer 34 and an upper conductive layer 42 made of the material of upper conductive layer 38. Correspondingly, counter-electrode fingers 32 also include a lower conductive area 44 and an upper conductive area 46.

The positions of electrode fingers 30 and counter-electrode fingers 32 relative to one another may be changed by interconnecting conductive areas 40 through 46 of electrode fingers 30 and counter-electrode fingers 32. The positions of frames 12, 14, and 16 relative to one another may also be changed according to the positions of electrode fingers 30 and counter-electrode fingers 32. Conventional methods for interconnecting conductive areas 40 through 46 include, for example, SEA (switch electrode actuator), and are not described in greater detail here.

For example, the inner one of the two frames 12 or 14 may be rotated in relation to the outer one of the two frames 14 or 16 around rotational axis 28 by an individual displacement angle using interconnection of areas 40 through 46 of two adjacent frames 12, 14, and 16. Of course, multiple frames 14 or 16 may also be rotated simultaneously in relation to outer frame 12 around rotational axis 28.

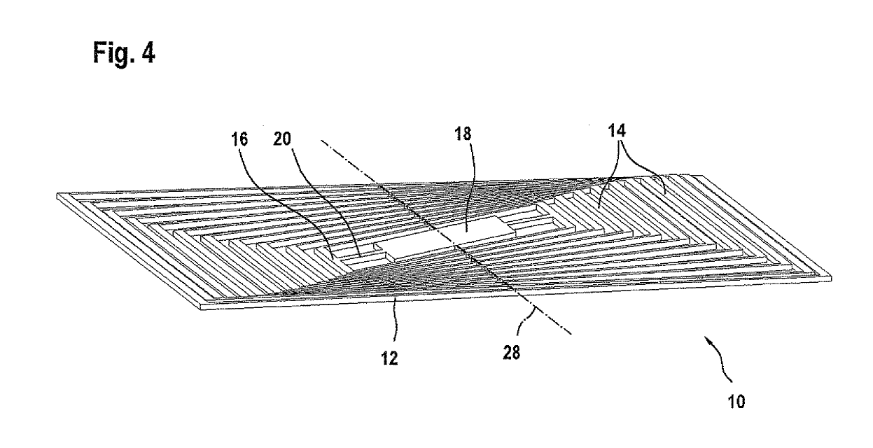

FIG. 4 shows a side view of the micromechanical component of FIG. 1.

The mode of operation of micromechanical component 10 is described on the basis of the illustrated side view. During operation of micromechanical component 10, all electrode fingers 30 and counter-electrode fingers 32 are simultaneously interconnected in such a way that associated frames 14 and 16 rotate in relation to outer adjacent frame 12 or 14 by an individual displacement angle. In particular, the individual displacement angles of all intermediate frames 14 and inner frame 16 may add up to form the greatest possible total displacement angle, by which inner frame 16 is rotated around rotational axis 28 in relation to outer frame 12.

Electrode fingers 30 and counter-electrode fingers 32, which are situated on frame bars 12a, 14a, and 16a, have a comparatively long distance to rotational axis 28. The torque of frames 14 and 16 which results upon interconnection of electrode fingers 30 and counter-electrode fingers 32 is therefore relatively high. This allows an implementation of short spring elements 22, 24, and 26 having a comparatively large width b1. In addition, frames 12, 14, and 16 having electrode fingers 30 and counter-electrode fingers 32, which are fastened directly on frame bars 12a, 14a, and 16a, require a comparatively small operating volume in their functional positions. This makes it easier to position micromechanical component 10 in a microsystem.

Actuator 18 is connected via the two connecting elements 20 to inner frame 16 in such a way that actuator 18 is also rotated by the total displacement angle in relation to outer frame 12 in the case of a rotational movement of inner frame 16. The relatively small individual displacement angles may add up to form a large total displacement angle due to the large number of frames 12, 14, and 16 which may be positioned within a comparatively small operating volume. In particular, the space-saving positioning of the electrode fingers (not shown) directly on frame bars 12a, 14a, and 16a of frames 12, 14, and 16 therefore ensures an increase of the total displacement angle.

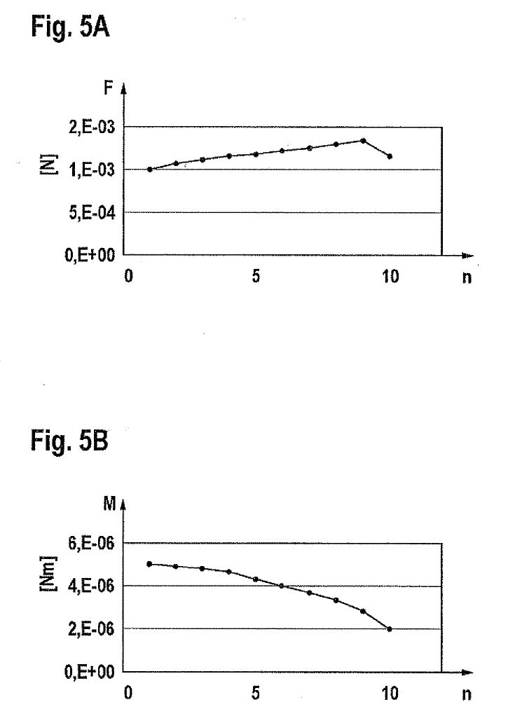

FIGS. 5A and B each show a coordinate system to explain a second specific embodiment of the electrostatic drive. The abscissas of the coordinate system specify a counting number n of an intermediate frame or inner frame if the intermediate and inner frames of the electrostatic drive are counted from the outside to the inside. The outer frame is not counted and has counting number 0. The outermost intermediate frame has counting number 1. In an electrostatic drive having 11 frames, the inner frame has counting number 10.

The ordinate of the coordinate system of FIG. 5A corresponds to a force F (in newtons), using which the associated frame is displaceable in relation to the outer frame. The ordinate of the coordinate system of FIG. 5B specifies associated torque M (in Nm).

Force F is established via the number and length of the electrode fingers and the number and length of the counter-electrode fingers between the frames having counting numbers n-1 and n. In the described specific embodiment, force F is to be nearly constant for all frames having counting numbers 1 through 10.

The longer the two frame bars of a frame are, the higher the number of the electrode fingers or counter-electrode fingers which may be situated directly on the frame bars. The most electrode fingers may be situated on the frame bars of the outer frame. The frame having counting number 10 is the shortest and therefore has the smallest number of electrode fingers. In order to nonetheless ensure a nearly equal force F for all frames having counting numbers 1 through 10, the length of the electrode fingers may be varied. The length of the electrode fingers preferably decreases with increasing counting number n in the case of counting from the outside to the inside. The length of the electrode fingers may decrease continuously.

For example, the outermost intermediate frame having counting number 1 has electrode fingers having a length of 50 μm. The length of the electrode fingers on the inner frame having counting number 10 may be 200 μm.

Through the implementation of comparatively shorter electrode fingers on the outer frames having a lower counting number n, a shorter distance is possible between the outer frames and therefore a reduction of the operating volume of the electrostatic drive while maintaining the number of frames. A micromechanical component having the electrostatic drive may therefore be minimized.

In spite of nearly constant force F for the frames having counting numbers n of 1 through 10, the outer intermediate frames having a lower counting number n have a high torque M because of the increasing distance of a (short) electrode finger to the rotational axis (FIG. 5B). The frames having a larger counting number n have a significantly smaller torque M because of their smaller distances to the rotational axis.

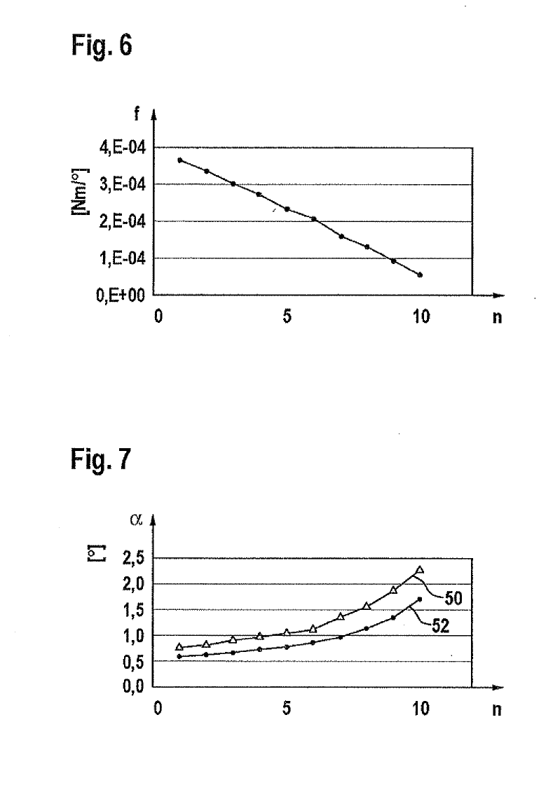

FIG. 6 shows a coordinate system to explain a third specific embodiment of the electrostatic drive. The abscissa of the coordinate system specifies counting number n if the intermediate and inner frames are counted from the outside to the inside. The ordinate indicates spring constant f (spring stiffness) of the at least one spring element (in Nm/°), via which the adjacent frames having counting numbers n-1 and n are connected to one another.

In the third specific embodiment of the electrostatic drive, the spring elements are designed in such a way that the spring elements situated on the outer frames have a comparatively high spring constant f and the spring elements situated on the inner frame have a relatively low spring constant f. Spring constant f of the spring elements decreases continuously with increasing counting number n, for example.

If the same voltage is applied to all electrode fingers, a nearly identical individual displacement angle may be ensured between all adjacent frames by the implementation of spring elements having a spring constant f which decreases with increasing counting number n. The decrease of the spring constant f with increasing counting number n therefore compensates for the torque, which decreases with increasing counting number n. In addition, it is ensured that each of the frames rotates by a constant maximum angle in relation to the adjacent outer frame in the case of an applied maximum voltage.

Of course, a combination of the second specific embodiment described on the basis of FIGS. 5A and B and the third specific embodiment described on the basis of FIG. 6 is also possible.

FIG. 7 shows a coordinate system to illustrate two examples of an achievable displacement angle. The abscissa of the coordinate system is counting number n in the case of counting the intermediate and inner frames of an electrostatic drive from the outside to the inside. The ordinate indicates displacement angle α (in °), by which the particular frame is displaceable in relation to the outer frame in the case of application of the same voltage between all frames.

Graph 50 indicates by how much each frame having counting number n is maximally rotatable. In the case of such an electrostatic drive, with a total number of 6 frames, i.e., with 4 intermediate frames, a maximum total displacement angle of approximately 6°, which is equal to the sum of displacement angle α of the frames having the counting numbers from 0 to n may be achieved. If the number of the frames is doubled to 10, a total displacement angle of 12° is thus achievable.

In contrast, graph 52 indicates displacement angle α by which a frame having counting number n is rotatable in the case of an applied voltage of 50 V, for example. As is noticeable upon a comparison of graphs 50 and 52, an achievable displacement angle α may be varied.

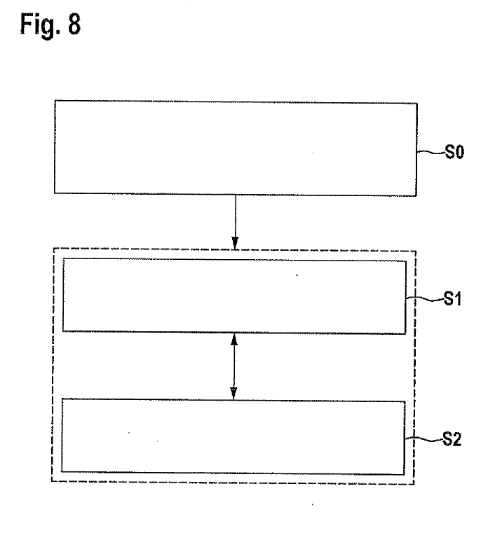

FIG. 8 shows a flow chart to illustrate a specific embodiment of the manufacturing method for an electrostatic drive.

In a step S0, which possibly precedes the described manufacturing method, a layer sequence is formed from a lower conductive layer, a middle insulating layer, and an upper conductive layer. For example, an SOI substrate (silicon-on-insulator) is manufactured. However, an SOI substrate is not required for performing the manufacturing method described here. Metals and/or silicon may also be applied to an insulating layer for the conductive layers.

In a first step (step S1) of the method, an inner frame, at least one intermediate frame, and an outer frame are structured out of the layer sequence. The at least one intermediate frame is situated around the inner frame. The outer frame is also situated around the inner frame and the at least one intermediate frame. Two adjacent frames are connected via at least one spring element. The spring elements between the frames are preferably also structured out of the layer sequence. The spring elements, via which the inner frame, the at least one intermediate frame, and the outer frame are connected to one another are situated in such a way that the longitudinal directions of the spring elements are on a common spring longitudinal axis.

Instead of above-described step S1, the inner frame, the at least one intermediate frame, and the outer frame may also be manufactured separately. The manufacturing method for the electrostatic drive begins in this case with situating the frames relative to one another, the frames being connected to the spring elements via the above-described way.

In a further step of the method (step S2), electrode fingers are situated directly on the frame bars of the frame which are parallel to the axis. This is performed in such a way that the longitudinal directions of the electrode fingers are oriented perpendicularly to the common longitudinal spring axis. Step S2 is preferably performed simultaneously with step S1. The electrode fingers may also be etched out of the layer sequence during the structuring out of the frames.

1-10. (canceled)

11. An electrostatic drive, comprising:
an inner frame;
at least one intermediate frame which encloses the inner frame;
an outer frame which encloses the inner frame and the at least one intermediate frame;
spring elements, wherein each two adjacent frames of the inner, intermediate, and outer frames are connected to one another via at least one of the spring elements, the spring elements being situated in such a way that longitudinal directions of the spring elements are on a common longitudinal spring axis; and
electrode fingers situated on frame bars of the inner frame, the at least one intermediate frame, and the outer frame, and the electrode fingers being oriented parallel to the longitudinal spring axis.

12. The electrostatic drive as recited in claim 11, wherein the inner frame, the at least one intermediate frame, and the outer frame are configured in such a way that a voltage may be applied between the electrode fingers, which are situated on the frame bars of two adjacent frames of the inner, intermediate, and outer frames, and the at least one spring element between the two adjacent frames is configured in such a way that a first frame of the two adjacent frames is rotatable around the longitudinal spring axis in relation to a second frame of the two adjacent frames by applying the voltage.

13. The electrostatic drive as recited in claim 11, wherein longitudinal directions of the electrode fingers situated on the frame bars of the inner frame, the at least one intermediate frame, and the outer frame, are oriented perpendicularly to the longitudinal spring axis.

14. The electrostatic drive as recited in claim 11, wherein one of the spring elements, which connects one of the intermediate frames to one of an outer adjacent intermediate frame or the outer frame, has a first spring stiffness, and another of the spring elements, which connects the one of the intermediate frames to one of the inner frame or an adjacent inner intermediate frame, has a second spring stiffness unequal to the first spring stiffness, and the second spring stiffness is less than the first spring stiffness.

15. The electrostatic drive as recited in claim 14, wherein the electrode fingers which are situated on the one of the inner frame or an adjacent inner intermediate frame have a first length, and the electrode fingers which are situated on the one of the outer adjacent intermediate frame or the outer frame have a second length, which is unequal to the first length, and the second length is less than the first length.

16. The electrostatic drive as recited in claim 11, wherein each of the electrode fingers includes a lower conductive area, a middle insulating layer, and an upper conductive area.

17. A micromechanical component, comprising:
an electrostatic drive, the electrostatic drive including an inner frame, at least one intermediate frame which encloses the inner frame, an outer frame which encloses the inner frame and the at least one intermediate frame, spring elements, wherein each two adjacent frames of the inner, intermediate, and outer frames are connected to one another via at least one of the spring elements, the spring elements being situated in such a way that longitudinal directions of the spring elements are on a common longitudinal spring axis, and electrode fingers situated on frame bars of the inner frame, the at least one intermediate frame, and the outer frame, and the electrode fingers being oriented parallel to the longitudinal spring axis; and
an actuator, which is connected to the inner frame in such a way that the actuator is rotatable around the common longitudinal spring axis by applying a voltage between the electrode fingers, which are situated on the frame bars of two adjacent frames of the inner, intermediate, and outer frames.

18. A method of manufacturing an electrostatic drive, comprising:
situating at least one intermediate frame around an inner frame;
situating an outer frame around the inner frame and the at least one intermediate frame, each two adjacent frames of the inner, intermediate, and outer frames being connected via at least one spring element, and the spring elements, via which each two adjacent frames of the inner, intermediate, and outer frames are connected to one another, being situated in such a way that the longitudinal directions of the spring elements are on a common longitudinal spring axis; and
situating electrode fingers directly on frame bars which are oriented parallel to the longitudinal spring axis, of the inner frame, the at least one intermediate frame, and the outer frame.

19. The method of manufacturing as recited in claim 18, wherein a layer sequence is formed from a lower conductive layer, a middle insulating layer, and an upper conductive layer, and the inner frame, the at least one intermediate frame, and the outer frame having the electrode fingers are structured out of the layer sequence.

20. A method of manufacturing a micromechanical component, comprising:
producing an electrostatic drive by situating at least one intermediate frame around an inner frame, situating an outer frame around the inner frame and the at least one intermediate frame each two adjacent frames of the inner, intermediate, and outer frames being connected via at least one spring element, and the spring elements, via which each two adjacent frames of the inner, intermediate, and outer frames are connected to one another, being situated in such a way that longitudinal directions of the spring elements are on a common longitudinal spring axis, and situating electrode fingers directly on frame bars which are oriented parallel to the longitudinal spring axis of the inner frame, the at least one intermediate frame, and the outer frame, wherein the inner frame, the at least one intermediate frame, and the outer frame are configured in such a way that a voltage may be applied between electrode fingers, which are situated on the frame bars of two adjacent frames of the inner, intermediate, and outer frames, and the at least one spring element between the two adjacent frames being configured in such a way that a first frame of the two adjacent frames is rotated around the longitudinal spring axis in relation to the second frame of the two adjacent frames by applying the voltage; and
situating an actuator on the inner frame in such a way that the actuator is rotated around the spring longitudinal axis by applying the voltage between the electrode fingers, which are situated on the frame bars of two adjacent frames of the inner, intermediate, and outer frames.
